(19) United States
(12) Patent Application Publication
(10) Pub. No.: US 2010/0237747 A1
(43) Pub. Date: Sep. 23, 2010

(54) Piezoelectric Composite Material

(75) Inventors: Noel Axelrod, Jerusalem (IL); Amir Lichtenstein, Tel Aviv (IL); Eran Ofek, Modi'in (IL); Vered Pardo-Yissar, Neve Monoson (IL)

Correspondence Address: EDWARD S. SHERMAN, ESQ., 3554 ROUND BARN BLVD., SUITE 303, SANTA ROSA, CA, 95403, US

(73) Assignee: Physical Logic AG, Zug (CH)

(21) Appl. No.: 12/790,954

(22) Filed: May 31, 2010

Related U.S. Application Data
(63) Continuation-in-part of application No. 11/611,619, filed on Dec. 15, 2006, now Pat. No. 7,728,492.
(60) Provisional application No. 60/751,863, filed on Dec. 19, 2005.
(60) Provisional application No. 60/794,959, filed on Apr. 26, 2006.

(51) Int. Cl. H01L 41/193; H02N 2/18; H01L 41/083

(52) U.S. Cl. 310/339; 310/363; 310/366

(57) ABSTRACT

A composition of matter having multiple layers of different conductors separated by thin layers of dielectric materials has a high piezoelectric coefficient when the conductors are metals having a significant difference in work function and the dielectric materials have a low elastic modulus when the metal layers are connected to form a capacitive circuit. Alternatively, when the conductors are semi-conductors they should have a significant difference in Fermi levels.

### CROSS REFERENCE TO RELATED APPLICATIONS

The present application claims priority to and is a Continuation-in-Part of the U.S. Non-provisional patent application of the same title which was filed on Dec. 12, 2006, having application Ser. No. 11/611,619, as well as the U.S. provisional patent application having application Ser. No. 60/751,863, entitled “Piezoelectric Composite Material”, which was filed on Dec. 19, 2005, both of which are incorporated herein by reference. The present application also claims priority to U.S. provisional patent application having application Ser. No. 60/794,959, entitled “Method and Device for Recharging Batteries”, which was filed on Feb. 26, 2006, which is also incorporated herein by reference.

### BACKGROUND OF INVENTION

The present invention relates to compositions of matter that exhibit piezoelectric phenomena, and more specifically to such composites formed from conductive and/or semi-conductive materials and dielectric materials.

Piezoelectricity is an effect by which energy is converted between the mechanical and electrical forms. The general form of linear coupling between stress tensor σ_{J} and polarization vector Pᵢ in direct piezoelectric effect is given by the equation

Pᵢ=d_{iJ}σ_{J} (1)

where d_{iJ} is the piezoelectric charge constants and indexes i={1, 2, 3}, J={1, 2, . . . , 6}. For index J the Voigt notation conversion is used.

Consider a crystal of piezoelectric material 10 with an electrical axis in the z direction (FIG. 1). Mechanical compression or tension acting in parallel to the z axis on the crystal induces excess of charge density

Δq=P₃=d₃₃σ₃ (2)

The conversion of mechanical forces into electric potential (charge excess) is known as direct piezoelectric effect. The inverse process of conversion of electric potential into mechanical motion is known as inverse piezoelectric effect.

Strong piezoelectric effects arise in solid materials having internal electric dipoles which are oriented either through the crystal structure or a poling process. When the dipoles are not oriented there affects largely cancel, resulting in no or very week piezoelectric effects. Examples of such materials include ceramic compounds, but also select organic polymers, such as polyvinylidene fluoride (PVF₂). In such polymers dipole orientation can be achieved by in both crystalline states and amorphous states by a combination of plastic deformation to orient polymer chains and crystallites, as well as a poling process.

A poling process exposes a potentially piezoelectric material to a high electric field via electrodes on opposing sides. The electric field, depending on the strength and characteristics of the material, as well as ambient conditions, cause the dipoles to orient and/or a permanent and stable separation of charges that form internal dipoles.

Thin film piezoelectric materials are known, and can be deployed with multiple electrodes Actuators are devices that moves in response to an electric stimulus. While the inverse piezoelectric effect can be exploited as an actuator, other form of actuators exist that do not exhibit the direct piezoelectric effect. Actuators that deploy multiple pre-strained polymer layers are described in U.S. Pat. Nos. 6,583,533; 6,628,040, 6,911,764, and 6,583,533, which are incorporated herein by reference. U.S. Pat. No. 6,911,764 asserts that the actuator described therein are capable of generating power when deformed, thus exhibiting the same characteristics as a direct piezoelectric effects. However, the disclosure requires the polymer to be electroactive polymer, which it defines as “When a voltage is applied to electrodes contacting an electroactive polymer, the polymer deflects”. Hence, the application of this method is limited to specific polymers, which are inherently capable of deflection, or may have enhanced deflection due to some level of pre-strain.

In addition for micro and nano-electromechanical systems, PbZn₁₋ₓTiₓO₃ wherein x is about 0.48 (PZT) is widely used in the form of thin films. However, PZT films, like other ceramic materials, are extremely brittle. Further, PZT thin films exhibit a hysteresis effect. In addition, the piezoelectric coupling constancies of PZT materials are strongly temperature dependant. The nonlinear effects, parameter variations, and other phenomena and effects observed in piezotransducers make it extremely difficult to integrate the piezotransducer dynamics. In fact, the steady-state analysis does not allow one to fully examine the system performance and make a conclusion based on requirements and specifications imposed.

It is therefore a first object of the present invention to provide piezoelectric materials for transducers, sensors and other applications that have a high piezoelectric coefficient yet are not brittle.

It is another object to provide piezoelectric materials for transducers, sensors and other applications that have a high piezoelectric coefficient that do not require either electro-active polymers or pre-strained polymer layers.

It is a further object of the invention to provide such piezoelectric materials in the form of thin films for ease of integration with micro electrical mechanical systems (MEMS) or nano-electrical mechanical systems (NEMS).

### SUMMARY OF INVENTION

In the present invention, the first object of providing a composition of matter with a high piezoelectric coefficient is achieved by forming a material having a series of layers having a periodic layered structure that itself comprises a first conductive material, a dielectric material, a second conductive material with a different work function/Fermi level from the first conductive material, followed by another layer of dielectric material. All the first conductive layers connect to a common first terminal. All the second conductive layers connect to a second common second terminal.

As the preferred form of the dielectric materials is an organic insulator, and more preferably a polymeric material, the composition is not brittle. Further, as the composition comprises multiple thin film layers it is amenable to incorporation of MEMS devices and integrated sensors.

The novel composite material is capable of use in MEMS (and larger), NEMS or other integrated devices to provide a power source by converting either single or periodic mechanical motion into electric power. Such miniature power supplies may be implanted in humans and animals for example to power various forms of implanted and leadless medical devices, including in-vivo monitoring of physiological functions.

The above and other objects, effects, features, and advantages of the present invention will become more apparent from the following description of the embodiments thereof taken in conjunction with the accompanying drawings.

### BRIEF DESCRIPTION OF DRAWINGS

FIG. 1 is a schematic diagram of a piezoelectric material showing the direction of applied stress.

FIG. 2 is a schematic cross section through a portion of a device deploying the novel composition of matter.

FIG. 3A is a plan view of mask used in a first step in fabricating piezoelectric material 100. FIG. 3B is a cross-sectional elevation along staggered section line B-B in FIG. 3A after deposition of the first metal layer 110 on a substrate or first dielectric layer 125. FIG. 3C is a cross-sectional elevation along staggered section line B-B in FIG. 3A

FIG. 4 illustrates another mask (A) in the process continuing from FIG. 3, along with a representative cross-sectional elevation at this stage (B).

FIG. 5 illustrates another mask (A) in the process continuing from FIG. 4B, along with a representative cross-sectional elevations at these stages (B, C).

FIG. 6 illustrates another mask (A) in the process continuing from FIG. 5C, along with a representative cross-sectional elevation at this stage (B).

FIG. 7A is a cross-sectional elevation illustrating the results of repeated applications of the steps shown in FIG. 3-6, whereas FIG. 7B illustrates in cross-section the result of one embodiment of one or more additional steps of connecting alternating conductive layers to electrodes.

FIGS. 8 A and B illustrate in cross-sectional elevations an alternative embodiment of a process of additional steps for connecting alternating conductive layers to electrodes.

FIG. 9A-D represents cross-sectional elevations of steps in another alternative embodiment.

FIG. 10 illustrates a sequence of fabrication steps in an alternative embodiment.

FIG. 11A is a perspective view of the layer shown in FIG. 10E being wrapped. FIG. 11B is a corresponding cross-sectional elevation of one embodiment of a piezoelectric device after fabrication is complete.

FIG. 12 shows the dependence of the piezoelectric charge constant d₃₃ on thickness of dielectric layers d for layered metal-insulator metal (LMIM) structure (solid line) and PZT5 ceramics (broken line).

FIG. 13 shows the dependence of the piezoelectric charge constant d₃₃ on thickness of dielectric layers d for three different LMIM structures and PZT5 ceramics

FIG. 14 shows the dependence of the piezoelectric charge constant d₃₃ on thickness of the dielectric layers over 5 orders of magnitude of total layers

### DETAILED DESCRIPTION

The following definitions will be helpful to appreciate that the invention disclosed herein has surprising and unexpected advantages over conventional and prior art devices that deploy one or more layers piezoelectric material or electroactive polymer, which is a polymer which deflects when actuated by electrical energy. Further, an inherently piezoelectric material is defined as a solid material that has internal dipoles that are cable of being oriented and polarized.

A poled piezoelectric material is an inherently piezoelectric material in which the internal dipoles have been at least partially oriented and polarized

A non-inherently piezoelectric materials is defined as a solid material that does not have internal dipoles that are capable of being oriented and polarized

An unpoled piezoelectric material is an inherently piezoelectric material in which the internal dipoles have not been at least partially oriented and polarized.

In light of the above definitions it will be further appreciated by one of ordinary skill in the art that an unpoled piezoelectric material would exhibit no greater direct or indirect piezoelectric effect than a non-inherently piezoelectric material of the same mechanical compliance at small strains when combined with the same electrode configuration in the same structure.

The present invention specifically deals with providing enhanced direct and indirect piezoelectric effects in non-inherently piezoelectric materials, unpoled piezoelectric materials and polymers other than electroactive polymers through an inventive layered metal insulator metal (LMIM) where the properties of the metal layers, and not the insulator, which is preferably a polymer or other soft inorganic solid elastic material, to provide direct and indirect piezoelectric effects. We thus further define herein a synthetic piezoelectric material as a solid material exhibiting direct and indirect piezoelectric effects that arise from the non-inherently piezoelectric materials, unpoled piezoelectric materials and non-electroactive polymers, and non-strained polymers.

It should be further appreciated that the inventive concepts disclosed herein, in the more preferred combinations may use any dielectric material, which might exhibit a weak or minor direct and indirect piezoelectric when used in multiple layers with the same metallic electrodes.

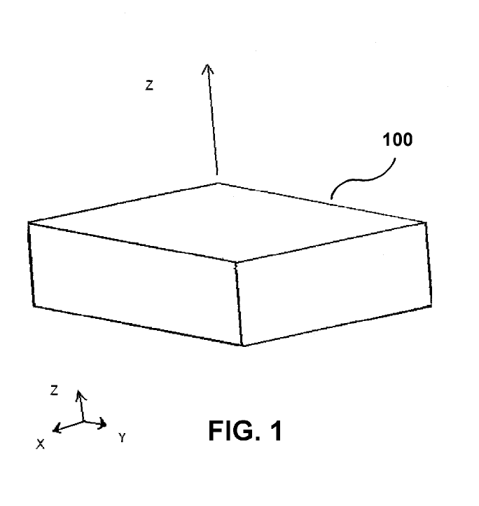

Referring to FIGS. 1 through 14, wherein like reference numerals refer to like components in the various views, there is illustrated therein a new and improved synthetic piezoelectric material, generally denominated 100 herein.

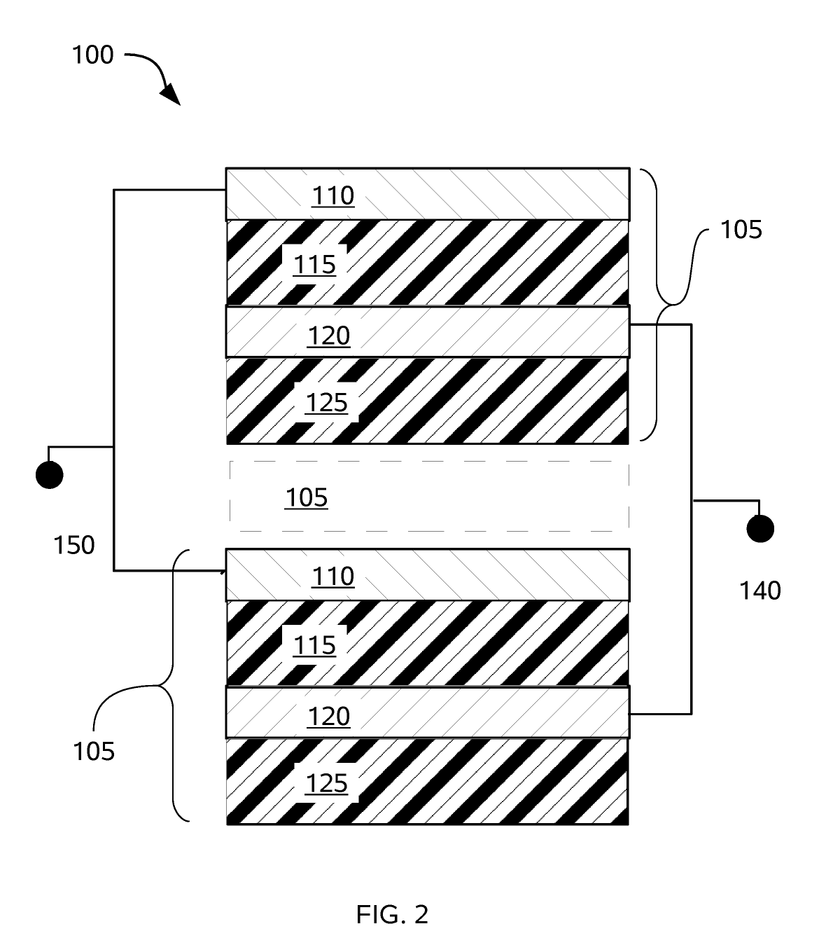

In accordance with one embodiment of the present invention, a synthetic piezoelectric material 100, as shown in FIG. 2 comprises a plurality of repeating units 105 having the layered structure of first a conductive layer 110, a dielectric 115, a 2^{nd} conductive layer 120 and another layer of dielectric 125. The first and second conductive layers are optionally metals or semi-conductors (organic and/or inorganic), including doped semiconductors. When the first and second conductive materials are metals they each have a different work function. When the different conductive materials are semi-conductors they each have a different Fermi level. Conductive layers have thickness d_{cond} and layers of dielectric materials have thickness d. As shown in FIG. 2, all first conductive layers 110 connect to a common first terminal 150. Further, all second conductive layers 120 connect to a second common second terminal 140. The device can be viewed as a system of N−1 capacitors connected in parallel, where N is the number of conductive plates. However, as each repeat unit 105 has two conductive layers N is 2 times the number of repeat units.

In other embodiments of the invention, which include methods of using the composite material, the first and second conductive layers need not be different metals or semi-conductors or have the same work function/Fermi level. Further, the term metal is intended to encompass alloys, inter-metallic compounds, as well as metal, alloys and compounds having sub-stoichiometric quantities of oxygen, nitrogen, carbon and the like, or much thinner layers of sub-oxides, nitrides or carbides that may not themselves be conductive.

Generally, the composition illustrated in FIG. 2 consists from equally spaced layers of conductive and dielectric materials. Further, the dielectric material is preferably an organic insulating material, such as an organic polymer, as will be better appreciated from the operative principles discussed below. The preferred values of d are expected to be in the range from 2 nm to 1000 nm.

Not wishing to be bound by theory, the following considerations are offered to explain the fundamental source of piezoelectric properties in the composition shown in FIG. 2. If Wₐ is a work function of the metal in the first conductive layer 110 and W_{b} is the work function of the metal in the second conductive layer 120, then the potential difference between two neighboring electrodes is φ=(W_{b}−Wₐ)/e. This is known as the contact potential. The electric field in the insulator layer is φ/d. This field could be extremely high for a thin insulator layer. For example, for φ=1 Volt and d=10 nm the magnitude of the field is 10⁷ V/m. As many insulator materials exhibit dielectric breakdown at such a high field, an insulating layer should be selected from a group of materials with a dielectric breakdown above that value, which includes of organic materials such as oils, lipids, polymers, elastomers, paper and the like. It should be appreciated that when the first and/or second conductive layers are semi-conductors, the Fermi level can be substituted for the work function when calculating the contact potential in the above equation.

When a pressure P is applied to the top of the devise in FIG. 2, parallel to the z axis, the applied pressure induces stress σ₃=P in the dielectric layers between the electrodes. As a result of the strain, the dielectric film is compressed. The corresponding change of the capacitance density (capacitance per surface area) is

$$Δ C = - N \frac{{ɛ}_{0} ɛ}{{d}^{2}} Δ d , \qquad ( 3 )$$

where N is the number of the dielectric layers and ∈ is the dielectric permittivity of insulator material. Using the equation below

$$\frac{Δ d}{d} = {u}_{3} = \frac{{σ}_{3}}{E} , \qquad ( 4 )$$

where u₃ is the strain, σ₃ is the stress in the insulator layer and E is the stiffness (Young's module) of the insulating material. Eq. (3) can be rewritten to express the change in capacitance as a function of the stress and elastic modulus as:

$$Δ C = - N \frac{{ɛ}_{0} ɛ}{Ed} {σ}_{3} , \qquad ( 5 )$$

The charge density excess on the electrodes due to applied pressure is then:

$$Δ q = Δ C ϕ = - N \frac{{ɛ}_{0} ɛϕ}{Ed} {σ}_{3} \qquad ( 6 )$$

Thus, combining the above result with the general expression for the piezoelectric phenomena from Eq. (2) results in the piezoelectric material 100 having a the piezoelectric charge constant d₃₃ of:

$${d}_{33} = - N \frac{{ɛ}_{0} ɛϕ}{Ed} . \qquad ( 7 )$$

The number of dielectric layers in the piezoelectric material 100 having a thickness h is

$$N = κ \frac{h}{d} \qquad ( 8 )$$

Where the coefficient

$$κ = \frac{d}{d + {d}_{cond}} .$$

Now, combining Eq. (7) and Eq. (8) expresses the piezoelectric charge constant in the following convenient form for appreciating several benefits of the invention:

$${d}_{33} = - κ \frac{{ɛ}_{0} ɛ h}{{Ed}^{2}} ϕ \qquad ( 9 )$$

As follows from Eq. (9), the piezoelectric charge constant of the piezoelectric material 100 is proportional to the thickness of the device h, to the contact potential φ and inversely proportional to both the stiffness E and to the square of the thickness of the insulating layer d. Thus, a dielectric insulating material, having a low stiffness, such as organic compounds and in particular polymeric materials, contribute to the desired outcome of a large piezoelectric effect. Further, it is desirable to make the insulating layer as thin as possible without exceeding its dielectric breakdown strength.

In an alternative embodiment of the invention, the first and second metal layers need not be a different composition or have a different work function when only the inverse piezoelectric effect is desired. If a voltage V is applied to the two leads of the device of FIG. 2, then the electrostatic force per surface area between the electrodes p will be

$$p = \frac{1}{2} {ɛ}_{0} {ɛ ( \frac{V}{d} )}^{2} . \qquad ( 10 )$$

This force is attractive independently on the sign of the potential V. The insulating layer is compressed under the applied force. Assuming that deformation of the insulating layer is elastic and small, using Eq. (4) we obtain

$$Δ d = - d \frac{σ}{E} = - \frac{1}{2} \frac{{ɛ}_{0} ɛ}{Ed} {V}^{2} . \qquad ( 11 )$$

Note, that the deformation is quadratic with the potential V. The minus sign in Eq. (11) corresponds to the compression. The total thickness change Δh within N layers of the LMIM structure is

$$Δ h = N Δ d = - \frac{N}{2} \frac{{ɛ}_{0} ɛ}{Ed} {V}^{2} . \qquad ( 12 )$$

Using Eq. (8) we have finally

$$Δ h = - \frac{κ h}{2} \frac{{ɛ}_{0} ɛ}{{Ed}^{2}} {V}^{2} . \qquad ( 13 )$$

This expression remains valid when the even and odd electrodes of the LMIM device are also made from different metals. For derivation of Eq. (13) we only assumed that the deformations are small and elastic. As follows from Eq. (13), the coupling between displacement and potential is quadratic. In contrast to this, this relation is linear in the classic inverse piezoelectric effect.

Noting that, E₃=V/d is the electric field within the dielectric layer we could rewrite Eq. (13) in the following form

$$\frac{1}{h} \frac{\partial h}{\partial {E}_{3}} = \frac{\partial ln ( h )}{\partial {E}_{3}} = - \frac{{κɛ}_{0} ɛ}{E} {E}_{3} . \qquad ( 14 )$$

From Eq. (2) and Eq. (7) that describes the direct piezo effect follows

$$\frac{\partial {P}_{3}}{\partial {σ}_{3}} = \frac{\partial Δ q}{\partial {σ}_{3}} = - \frac{{κɛ}_{0} ɛ}{E} \frac{ϕ}{d} . \qquad ( 15 )$$

It is worth to note, that Eq. (14) coincides with the Eq. (15) if one will substitute E₃ instead of φ/d in Eq. (15).

In contrast, for the classical piezoelectric phenomena (as was obtained by Lippmann in 1881 from general thermodynamic principles) the following equality holds:

$$\frac{\partial {P}_{3}}{\partial {σ}_{3}} = \frac{\partial ln ( h )}{\partial {E}_{3}} = {d}_{33} . \qquad ( 16 )$$

The aforementioned equations are now utilized to provide a theoretical example of an embodiment of the invention for a multilayered structure consisting from thin layers of gold and aluminum with an elastomer between them. The thickness h of the composite is assumed to be 1 mm and the thickness of metal and dielectric layers d=d (metal) is assumed to be 100 nm. The work function of gold and aluminum is 5.1 eV and 4.1 eV respectively. So, the contact potential between them is φ=1 V. The Young modulus of the elastomer is 1.6 MPa. And the dielectric permittivity of the dielectric layers is about 3.5. Using basic structure shown in FIG. 2 has a total of 8 layers, with a thickness of each layer being 100 nm, the total number of repeats of this layer would be 1,250 (1 mm/800 nm)

Using Eq. (9) we could calculate the dielectric charge constant for this structure:

d₃₃=−1×10⁻⁶ C/N=−10⁶ [pC/N]

That number could be compared with the dielectric charge constant of the PZT5 ceramics: d₃₃=590×10⁻¹² C/N. Thus surprising, the direct piezoelectric effect for the theoretical structure is about 1700 times higher than in conventional piezoceramics.

The charge constant in the inverse piezoelectric effect for this structure depends on the applied voltage and is equal from Eq. (13) to

d₃₃^{inv}=−3.5×10⁻⁷ V [m/V]

where V is the voltage applied to the two leads of the system (in volts). For V=10 Volts, this coefficient is 6000 times higher than d₃₃ of the PZT5, an unexpected result.

It will be appreciated by one of ordinary skill in the art, that numerous alternative embodiments of the invention exist that use different materials than those give in the above examples. Such alternatives include the variations in metals and metal pairs are from Au/Al. Accordingly, alternative metal pairs include any combination of Au, Pl, Co, Ni with Li, Al, Ca, Mg, Zn and the like. Generally, the thickness of the metal layers is at least 1 nm. Following are options for materials comprising the conductive couples:

Two metals, a metal and a doped in-organic semiconductor, metal and doped organic semiconductor (conductive polymer), metal and metal treated by a self assembled monolayer in order to change the working function of the metal with the same metal with a self assembled monolayer (Au with a self assembled monolayer of disulfide or thiloated hydrocarbon for example) as well as any possible combination of the possible conductive layers described above or other conductive materials.

It should be understood that such conductive layers can have substantially the same composition but differ in work function or Fermi level by doping or surface treatment. It also conceivable that the conductive layer can be formed by depositing a dielectric layer and then doping or otherwise treating one or both surfaces, by doping, ion implantation and the like so that the treated surface becomes conductive but is separated from the adjacent conductive layer by the other side or core of the deposited dielectric it was derived from.

Further, the dielectric material is preferably a polymer or lipids. More preferred polymers have a dielectric breakdown strength of greater than about 10⁷ V/m (or about 250 KV/in.). Additionally the thickness of the dielectric or polymer layer is preferably from about 10 nm to about 100 nm. The dielectric layer in fact can be a liquid or liquid crystalline material so long it is capable of supporting the intervening metal layers.

The dielectric layer should be elastic (the preferred young modulus is in the range of 1.6-500 MPa, however, the range can vary depending on the required application) such as: Polybutadiene elastomer, Polyurethane elastomer, PDMS elastomer, Rubbers, EPDM rubber (ethylene-propylene-diene-monomer-rubber), nitrile rubber, styrene-butadiene-styrene (SBS) rubber, PVDF (polyvinylidene fluoride), etc. And have the highest dielectric constant possible for example: PMMA/BaTiO composite (not very elastic but has very high dielectric constant), Lipids etc.

It should also be appreciated that the surprisingly large piezoelectric constants of the inventive synthetic piezoelectric material 100 can achieved using dielectric layers 115 and 125 that are either non-inherently piezoelectric materials as well as unpoled piezoelectric material.

However, the inventive synthetic piezoelectric material 100 can also deploy dielectric layers 115 and 125 that are poled piezoelectric materials. However, in this case the resulting piezoelectric properties will be stronger than if the same poled piezoelectric materials where used in a device that deployed metals electrodes of the same composition.

Further, as known piezoelectric materials that could be used as dielectric layers 115 and 125 are limited, and pose practical difficulties in either deposition at optimum thicknesses to enhance piezoelectric properties per equation, or would require poling, it would not be of practical utility to deploy such material for a substantial portion of the device. Hence, it is desirable that substantially all of the piezoelectric properties of such a device are provided by the deployment of the different metal layers 110 and 120 with either non-inherently piezoelectric materials as well as unpoled piezoelectric material. More preferably, substantially all of the piezoelectric properties of such a device are provided by the deployment of the different metal layers 110 and 120 with either non-inherently piezoelectric material that are low modulus elastomers of lipids having a high dielectric strength.

The inventive structure of FIG. 2, and related embodiments of the invention, may generally be fabricated by known methods of fabricating multilayer capacitors, but preferably by those that allow the controlled deposition of very thin layers of organic insulators. Such suitable methods are disclosed in U.S. Pat. Nos. 6,092,269 (to Yializis, et al., issued on Jul. 25, 2000), 5,736,448 (to Saia, et al., issued Apr. 7, 1998), which are incorporated herein by reference. Specific preferred polymers are those that are known for their facile deposition in the form of thin films, and include without limitation the polymers Parylene™, polymers formed from the monomers hexadioldiacrylate, triethylene glycol diacrylate, trimethylolpropaneethoxy-triacrylate, tetraethyleneglycol-diacry-acrylate, polyethylene glycol diacrylate and the like.

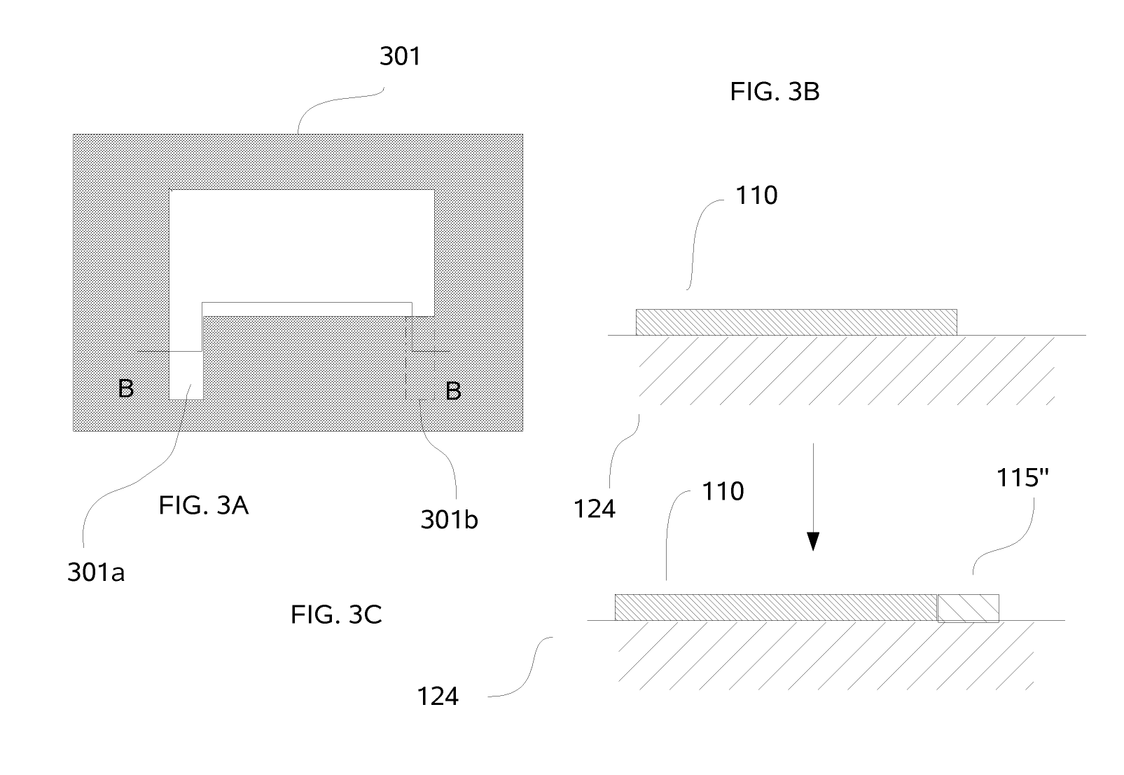

FIGS. 3-8 illustrate a method of fabricating piezoelectric material 100. In the series of FIG. 3-6, Fig. A in the series represents a mask used for either metal or dielectric layer deposition and/or patterning. FIG. B being a cross-sectional elevation through the structure at reference line B-B in the corresponding FIG. A. If the conductive materials are metal or inorganic semiconductors that can be deposited by Physical or Chemical Vapor Deposition. Organic dielectric materials can also be deposited from the vapor state, such as PARYLENETM (poly para-xylylene and related analogs), but may also be deposited by spin coating, controlled dip or curtain coating from a dilute solution, as well as known methods of forming of transferring Langmuir-Blodgett films.

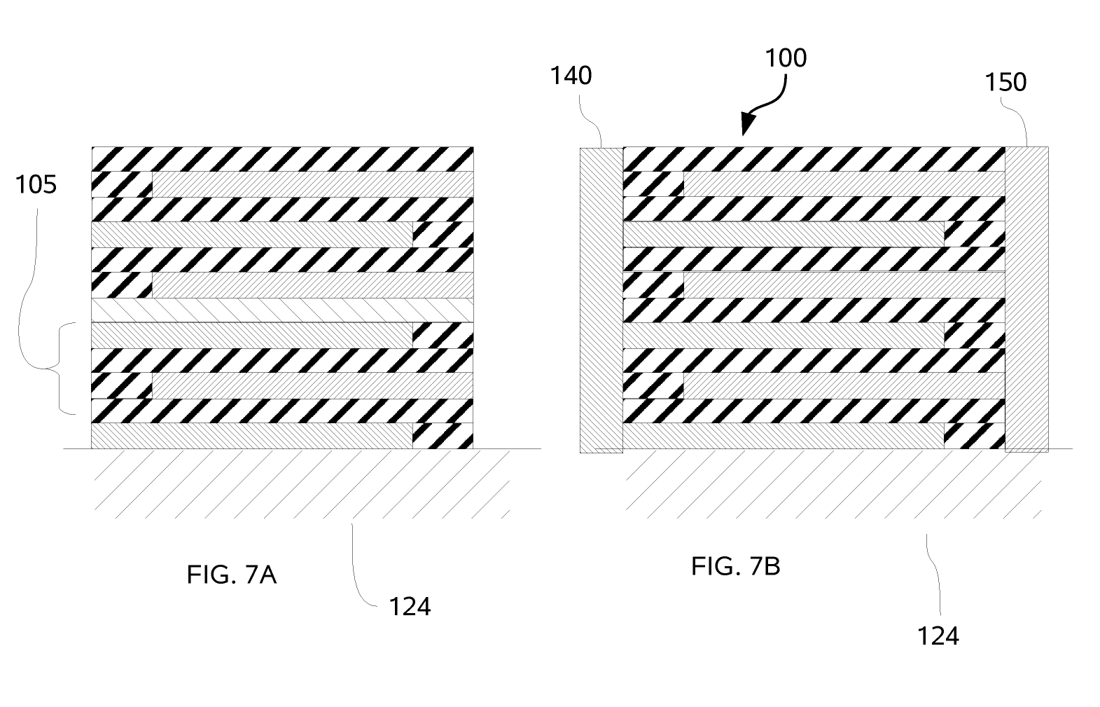

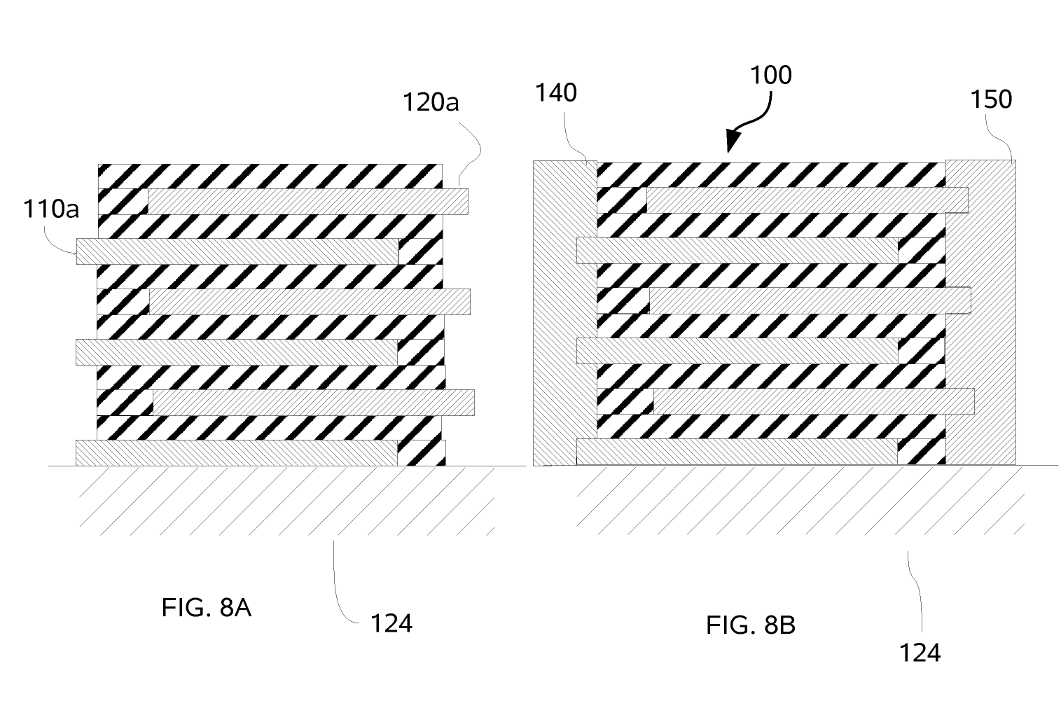

Thus, referring first to FIG. 3A, mask 301 has a generally central rectangular opening with a “finger” 301a intended for connection of a left electrode, shown as 140 in FIGS. 7B and 8B. Also shown in this FIG. is the outline 301b of an opposite “finger” in other masks used in the process, intended to define the structure for connecting the right electrode.

In FIG. 3B, a first metal layer 110 is deposited on substrate 124, which is optionally a dielectric layer that becomes a part of the device, or a thin sacrificial layer on a thicker rigid substrate, such as a silicon wafer so that the structure 100 can be released from the wafer. In the next step, the result of which is illustrated in FIG. 3C, dielectric material 115′ is deposited to fill the region 301B that does not have a metal layer 110 due to the masking of 301.

It will be appreciated by those of ordinary skill in the art that this region of dielectric filler 115′ can be formed by multiple methods, such as depositing a dielectric material through a mask, as well as coating an entire dielectric layer and then using photolithographic techniques to remove the excess dielectric material covering the first metal layer 110. Thus, any reference to a mask for patterning refers to coating through a mask, as well as coating a continuous layer, and then using a mask to pattern a photoresist layer. It will be appreciated that the contrast of the mask may be inverted for a negative versus positive.

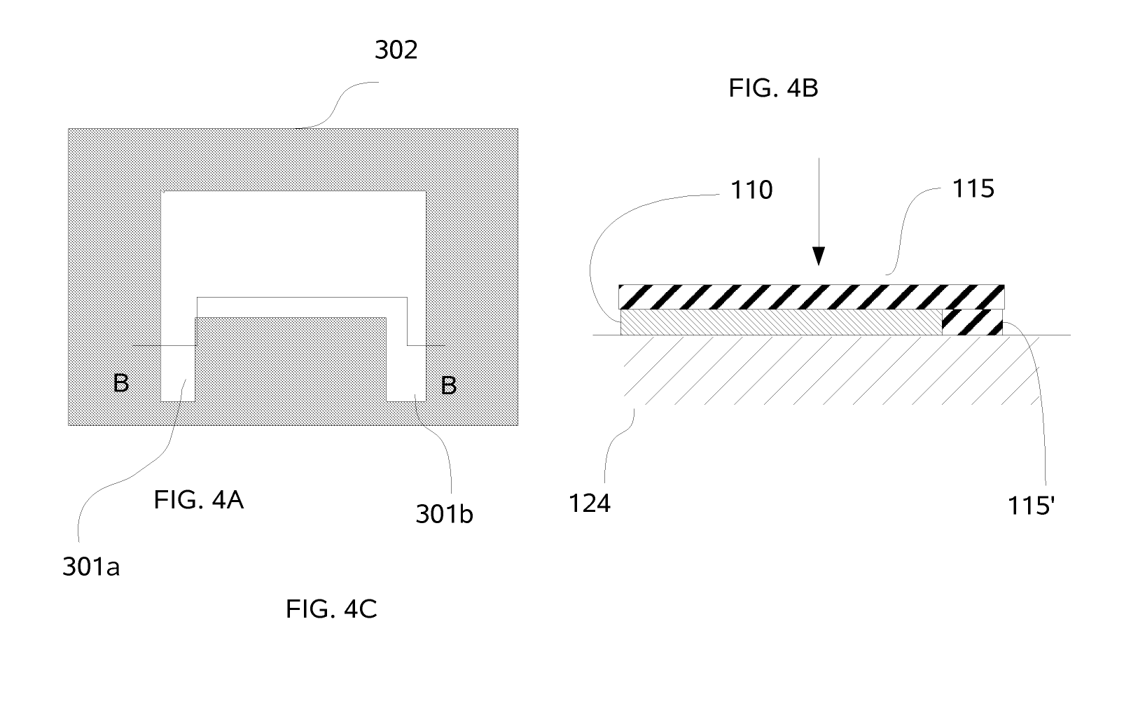

In the next steps, illustrated by FIGS. 4A and 4B, the mask 302 is used to define or deposit a continuous dielectric layer 115 over both layer 110 and the dielectric portion 115′. It should be noted that in mask 302, both portion 301a and 301b are now open.

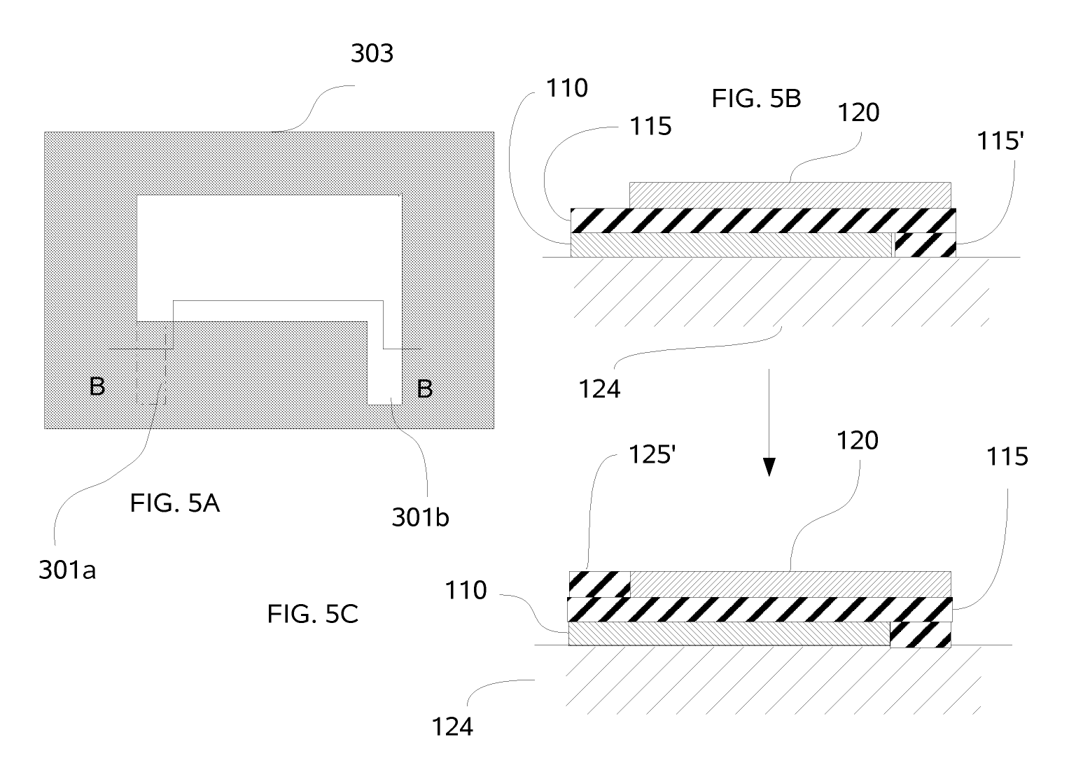

In the following step, shown in FIG. 5B a second metal layer 120 is deposited on the portion of the dielectric layer 115 corresponding to the opening in mask 303. It should be noted that as shown in FIG. 5A, for mask 303 the portion 301b is now open, whereas the portion 301a is closed. In the next step, the result of which is illustrated in FIG. 5C, dielectric material 125′ is deposited to fill the region 301a that does not have a metal layer 120 due to the masking of 303.

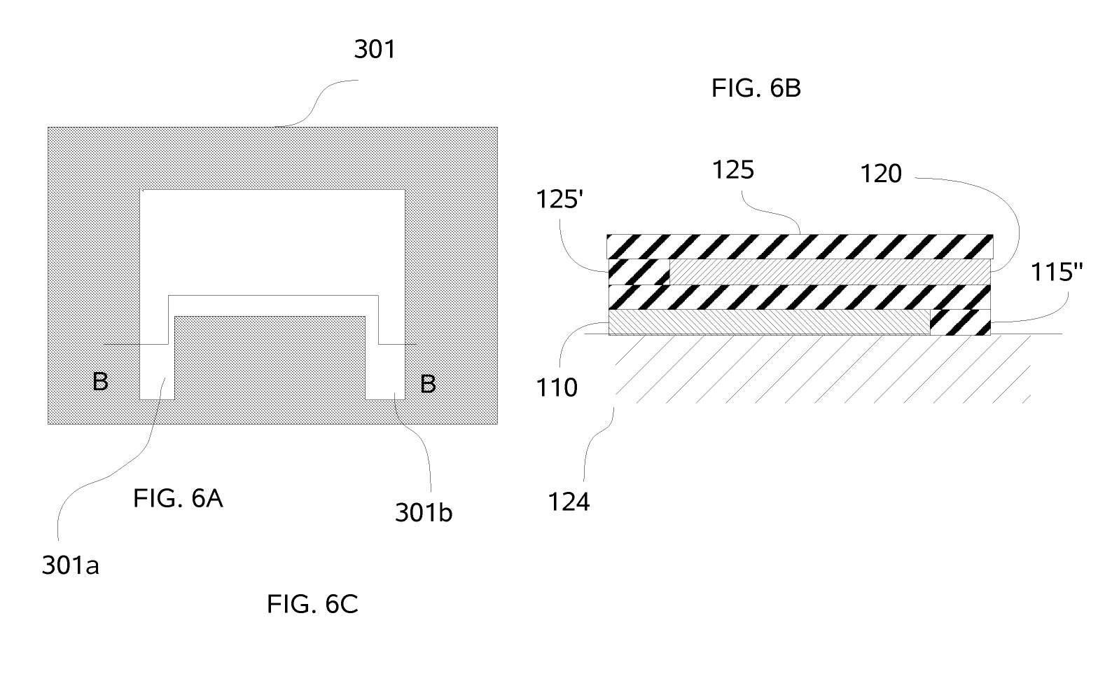

In the next steps, illustrated by FIG. 6B, the mask 302 (shown again in FIG. 6A) is used to define or deposit a continuous second dielectric layer 125 over both the second metal layer 120 and the dielectric portion 125′. It should be noted that in mask 302, both portion 301a and 301b are now open. It should be appreciated that the same or a different dielectric material than that denominated 115 in FIG. 4B may be deposited as the dielectric layers 115′, 125′ and 125 in other steps.

Thus, the conclusion of the step described with respect to FIG. 6 the multiple layer structure has a central portion of what is essentially the fundamental repeat unit 105 having the layered structure of first a conductive layer 110, a first dielectric 115, a 2^{nd} conductive layer 120 and another second dielectric layer 125.

FIG. 7A is a cross-sectional elevation representing the structure formed from repeated applications of the steps in FIGS. 3-6, wherein multiples of repeat units 105 are deposited in sequence.

FIGS. 7B and 8A and B illustrate alternative methods of adding electrodes 140 and 150. ideally the previous process steps leave all the first conductive material layer 110 exposed on the left side of the structure in FIG. 7A, and all of the second conductive material layers 120 exposed on the right side. In such a case, known processes of metal deposition and filling can be used to connect all of the first conductive layers to each other as well as all the second conductive layers to each other, that is forming electrode 140 and 150 shown in FIG. 7B. Such metal filing or deposition of electrodes 140 and 150 can be carried out by Physical Vapor Deposition, Chemical Vapor Deposition or electroless plating of copper or nickel and the like.

However, depending on the nature of the dielectric deposition and/or planarization process it may be necessary to selectively remove or etch dielectric material from each side used to connect electrode 140 and 150. Both sides may be etched simultaneously or each side in a separate sub-step. Slow wet etching of organic dielectric layers is preferable so that metal or other conductive material layers 110 and 120 are not disturbed.

Preferably, the dielectric layers 125 and 125′ are only partially removed in the “fingers” or regions defined by portion 301a and 301b of the masks 301, 302 and 303. The limited etching can be done by first masking the area not to be etched. Alternatively, depending on the selection of the dielectric layers 125 and the conductive layers 110 and 120, such selective etching may be carried out by reactive gas plasma or directed ion beam process.

In either case, this etching step leaves portion 110a of the first set of alternating metal layers protruding slighting from the left side. The etching step also leaves portion 120a of the second set of alternating metal layers protruding slightly from the left side. Accordingly, after such etching process, electrode 140 and 150 can be deposited by the previously described methods to form the piezoelectric material 100 shown in FIG. 8B.

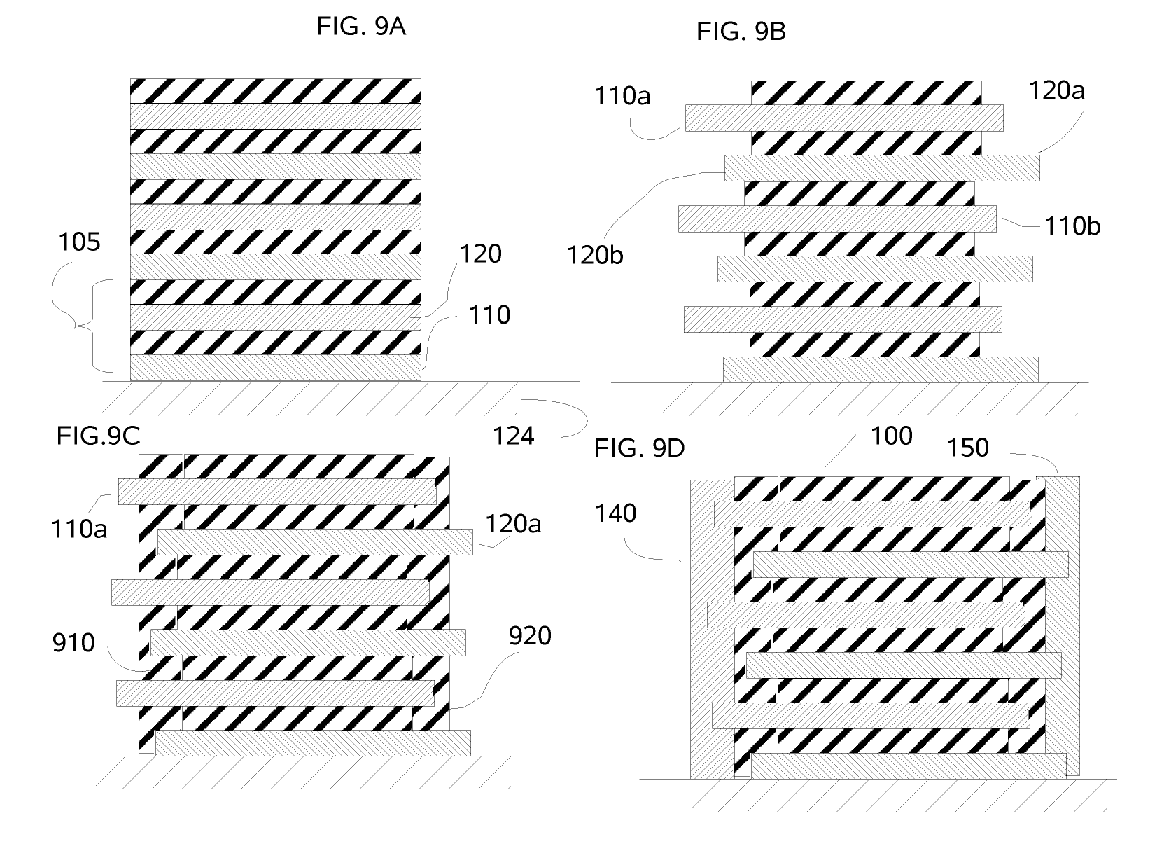

FIG. 9A-D illustrates an alternative method of forming piezoelectric material 100. Instead of depositing staggered layers by masking as shown in FIGS. 3-8, planar alternating layers of repeating structure 105 are formed, as shown in FIG. 9A. Then based the selective application of chemical etching agents that etch one conductive layer faster than the other, each of the left and right side are etched so that alternating conductive layers of each type protrude on opposite sides as shown in FIG. 9B. Also shown in this figure is that dielectric layers have been etched back more than the metal layers. The dielectric etching may be conducted before, after or simultaneously with the selective metal etching. Thus, in FIG. 9B, first conductive layer 110 have a left end portion 110a that protrudes to the left more than the left end portion 120b of the second conductive layers 120. In complementary contrast, on the right side second conductive layers 120 have right end portions 120a that protrudes to the right more than the right end portion 110b of the first conductive layer 110.

Next as shown in FIG. 9C, in one or more steps the left and right ends are at least partially coated with dielectric layers 910, on the left, and 920, on the right so that only protruding ends 110b and 120b are covered. Then, as shown in FIG. 9D, the left protruding ends 110a of the first conductive layers are coated with metal to form electrode 140, whereas the right protruding ends 120a of the second conductive layers 120 are coated with metal to form electrode 150, to piezoelectric material 100 to form a charge or current generating device.

The methods of FIGS. 7-9 can be formed by being deposited for example on a smooth silicon wafer by the following process. First, the silicon wafers are cleaned with UV ozone, plasma, or so-called Piranha solutions, and then preferably are annealed at 150 C for 5 h in vacuum, to achieve hydroxylated silicon wafers. Next, the polydimethylsiloxane (PDMS) film as the first dielectric layer is deposited by the direct spin coating of toluene solutions onto the hydroxylated silicon wafers Then, but prior to the deposition of a first conductive layer, such as gold (Au), the exposed PDMS surface is activated for increasing the adhesion to the Au by reactive ion etching (RIE) in oxygen for about 1-15 seconds. Next, the gold is deposited by chemical or physical vapor deposition. Preferably prior to the next PDMS spin-coating (on the Au layer), The Au layer is pre-treated with a solution containing a molecular species that is capable of forming a self assembled monolayer (SAM), such as alkanethiol inks. In particular, an Au layer modified by a thiolated monolayer will have a much lower working function than its natural work function.

Again, a second dielectric layer of PDMS is deposited by spin coating from a toluene solution. Again the PDMS is preferably activated to improve adhesion to the second conductive layer. Then, a second conductive layer of either copper (Cu) or silver (Ag) deposited by chemical or physical vapor deposition.

Preferably prior to the next PDMS spin-coating (on the Ag or Cu layer), this layer is pre-treated with a solution containing a molecular species that is capable of forming a self assembled monolayer (SAM), such as alkanethiol inks Now that repeat unit 105 has been formed, the previous steps are repeated for achieving the desired number of repeat unit or total layers. In the next steps of the selective etching of the PDMS at each side and different metal a preferred method is to use a slow etching process for better control of the etching process. A PDMS dielectric layer can be etched with tetrabutylammonium fluoride (C₁₆H₃₆FN)+n-methyl-2-pyrrolidinone (C₅H₉NO) 3:1. Au can be etched with aqua regia, but preferably hot sulfuric acid containing 4 g:2 g:10 ml-KI:I₂:H₂O Hot, for example at about 70° C., for an etch rate of about 280 nm/min or with 9 g:1 g:50 ml-NaBr:Br₂:H₂O (for an etch rate of about 400 nm/min.) Ag can be etched with 3:3:23:1 H₃PO₄:HNO₃:CH₃COOH:H₂O (for an etch rate of about ˜10 min/100 A) and Cu can be etched with any of 30% FeCl3 saturated solution, 1:5-H₂O:HNO₃, HNO₃ concentrated and dilute, 1:1-NH4OH: H₂O₂, 1:20-HNO₃: H₂O₂, 4:1-NH₃: H₂O₂, 1:1:1-H₃PO₄:HNO₃:HAc, 5 ml:5 ml:4 g:1:90 ml-HNO₃:H₂SO₄:CrO₃:NH₄Cl: H₂O as well as 4:1:5-HCL:FeCl₃: H₂O

However, depending on the ultimate fabrication process more preferred pairs of conductive materials used to achieve a greater difference in work function, might include Pt or Ge as a first conductive material (work function about 5.1-5.93 for Pt, and about 5 for Ge) and either at least one of AgOCs (having a work function of about 1) or semiconductors (p-doped) covered with a thin layer (n-doped) potentially having a work function of less than 1.

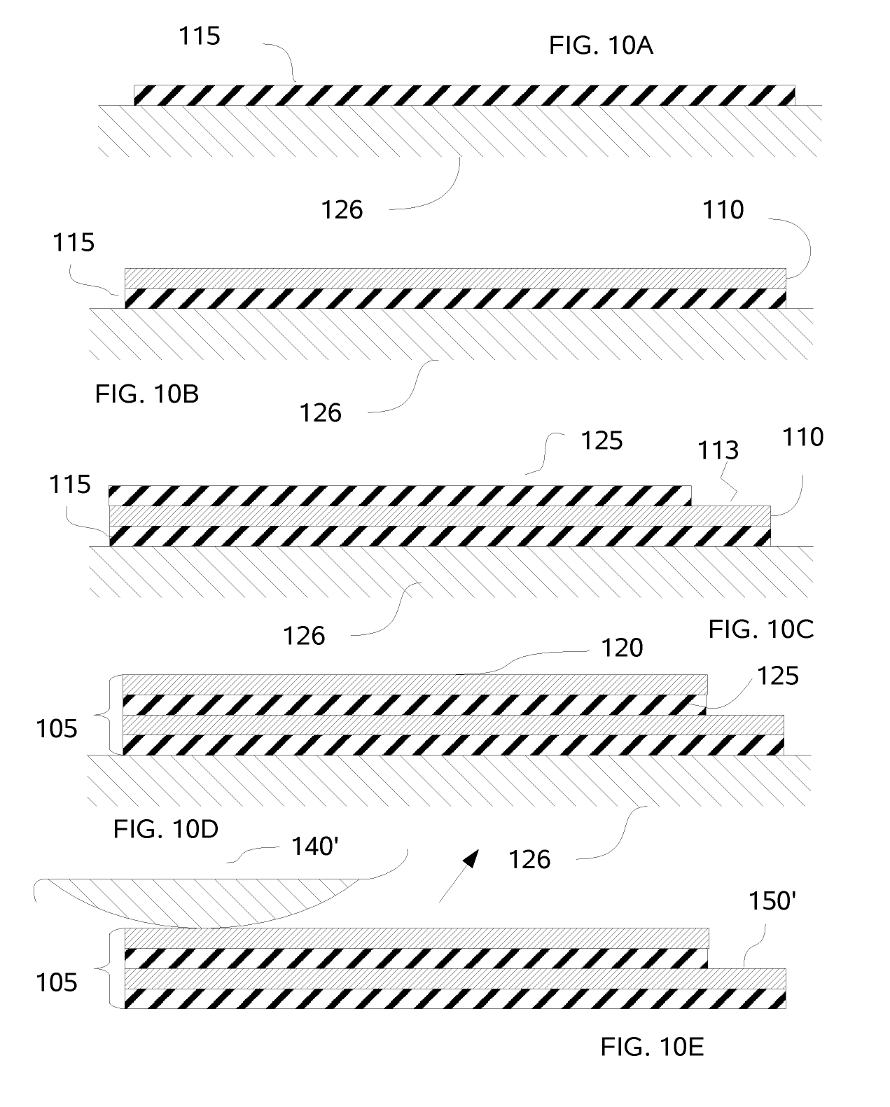

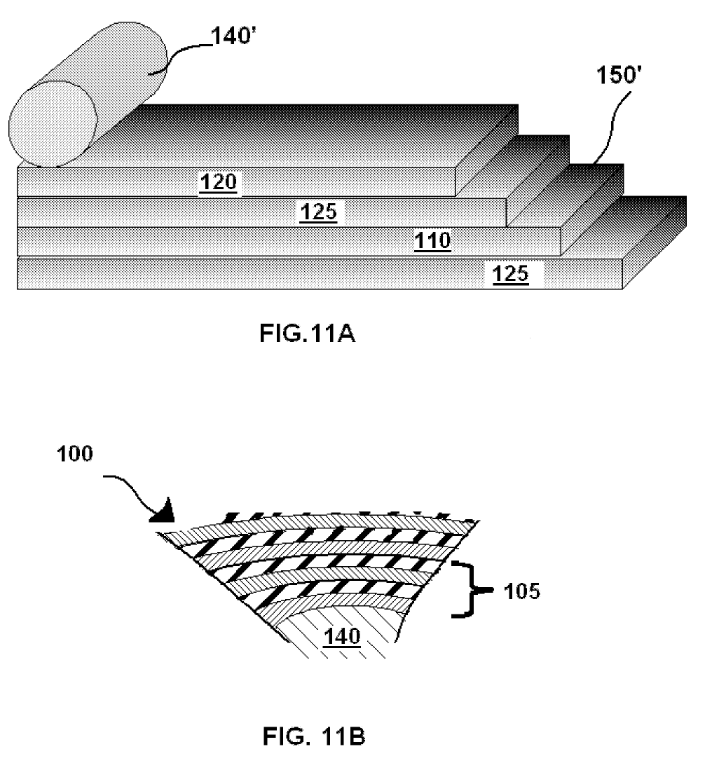

An alternative method is illustrated in FIGS. 10 and 11, wherein the alternating dielectric layers are first coated on a releasable substrate 126.

Although this description starts with the deposition of the first dielectric layer 115, it will be recognized that alternative sequences are possible so long as an exposed edge of other portion of the first conductive layer 110 and second conductive layer 120 are accessible for contacting electrodes, but isolated by the dielectric layers 115 and 125.

Thus, the first step in this embodiment is depositing the first dielectric layer 115 on substrate 126, as illustrated in FIG. 10A.

Next, referring to FIG. 10B the first conductive layer 110 is deposited in on the first dielectric layer 115.

Then, as shown in FIG. 10C, the second dielectric layer 125 is deposited to cover all but an edge portion 113 of the first conductive layer 110.

Then, as shown in FIG. 10D, the second conductive layer 120 is deposited on the second dielectric layer 125. Next, the combination of layer 115, 110, 125 and 120 (which is repeat unit 105) is removed or released from substrate 126, so that is can be wrapped multiple times around a conductive mandrel 140′, to created a laminated multilayer structure acts as on electrode connecting all of the second conductive layer 120. A partial cross-section of such as device is shown in FIG. 11B, with the wrapping shown in a perspective view in FIG. 11A.

Thus, after wrapping the exposed edge portion 113 of the first conductive layer is available to as electrode 150′, or may have an electrode connected in electrical communication therewith.

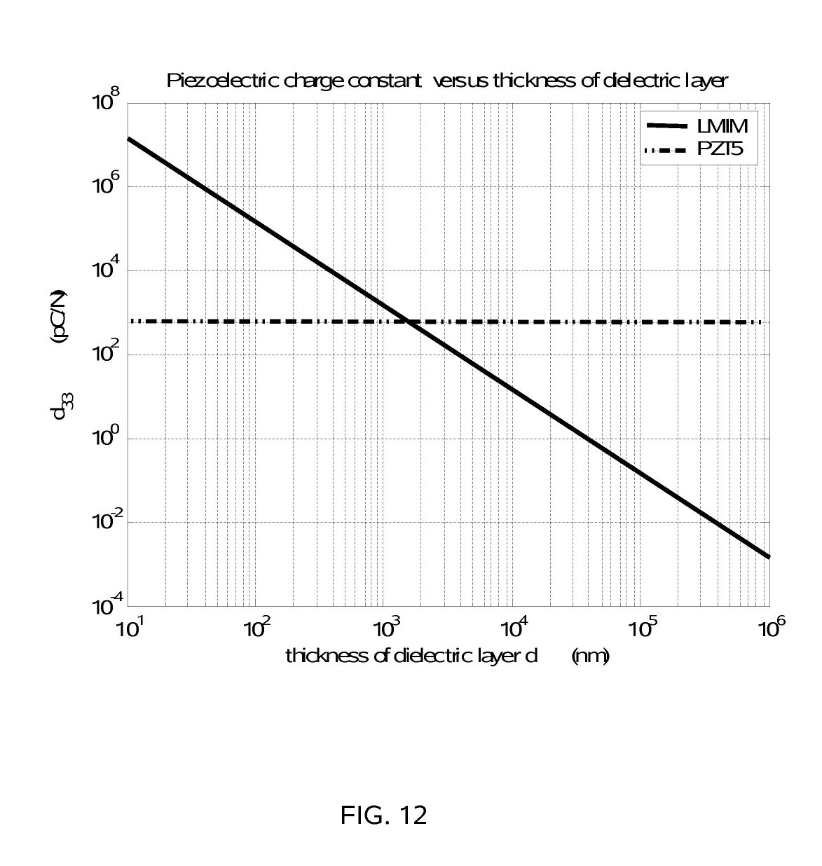

FIG. 12 through 14 illustrate comparative theoretical examples of the inventive materials in comparison to prior art piezoelectric materials using equations 7-9.

FIG. 12 shows the dependence of the piezoelectric charge constant d₃₃ on thickness of dielectric layers d for layered metal-insulator metal (LMIM) structure (solid line) and PZT5 ceramics (broken line).LMIM has a constant total thickness, T, and that as the dielectric thickness, t, decrease there are more layers, where n is the number of layers T=2n(t_{dielectric}+tₘₑₜₐₗ).

The coefficient k in the Eq. (2) is given by k=t_{dielectric}/(t_{dielectric}+tₘₑₜₐᵢ).

The dielectric material in the FIG. 12 is Polymethylmethacrylate (PMMA).

Alternatives to PMMA include Nylon, Polyimide, Polyethylene, PTFE, PVC, Silicones and the like, provided one takes into account the differences in elastic modulus and dielectric constant. The primary requirement to the dielectric material is to provide thin homogeneous layer that electrically isolate the metal layers.

The following properties of the dielectric material (PMMA) are assumed in FIG. 12:

∈=3; h_total=5 mm and E=3×10⁹ Pa;

The thickness of the metals in this example is assumed much less than the thickness of the dielectric layer (k=1). The metals are also assumed to have the difference of the work function 1.5 V. (such as Li—Ni) The d₃₃=590 pC/N of PZT5 is given for reference. The metal layer should be reasonably good conductor with a work function that depends weakly on the thickness, that is it does not modify the work function of one metal or conductor up or down to lessen the difference, Φ.

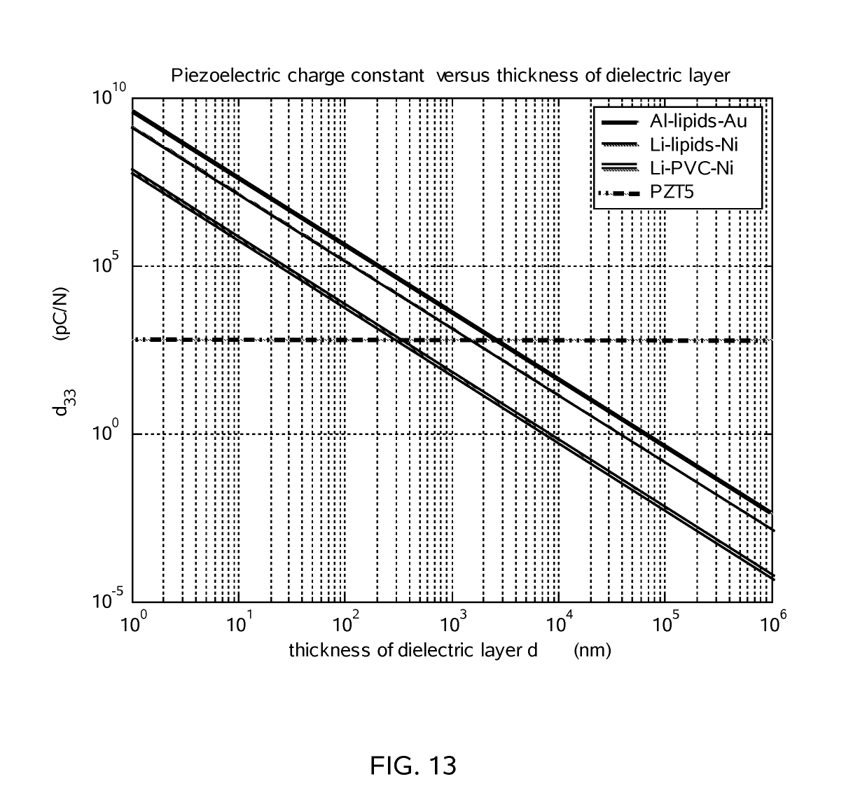

FIG. 13 shows the dependence of the piezoelectric charge constant d₃₃ on thickness of dielectric layers d for three different LMIM structures and PZT5 ceramics. The metal pairs are indicated in the caption to FIG. 13, with either polyvinyl chloride (PVC) or a lipid as the dielectric material. PVC is a standard material in MEMS device fabrication processes, being relatively easy to deposit as thin films. The elastic constant for the lipid layers is about 7×10⁵ Pa. These three different LMIM structures have the indicated metal layers with equal thickness of about 2 nm. As the device thickness remains 5 mm, the number of layers varies with the thickness of the dielectric layers. In a preferred embodiment, which exceeds the performance of PZT5, the dielectric thickness should be about 300-400 nm or less, with a total of 10,000 or more dielectric layers.

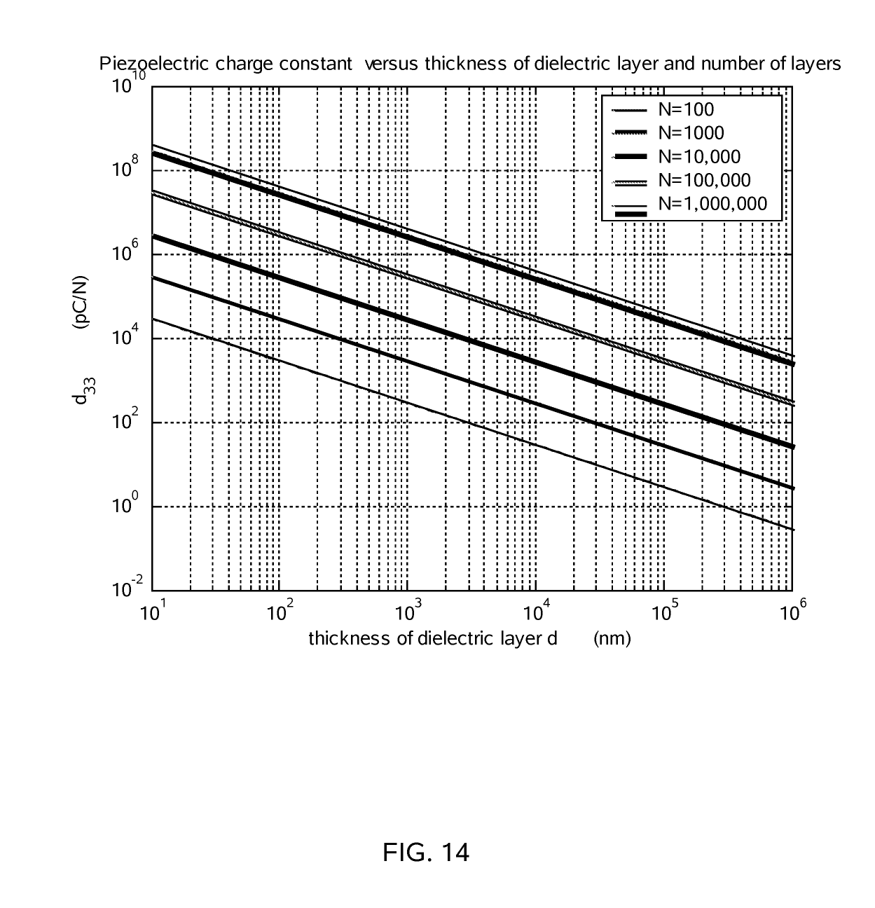

FIG. 14 shows the dependence of the piezoelectric charge constant d₃₃ on thickness of dielectric layers d and numbers of dielectric layers N for a Lipid-Ni LMIM structure. Thickness of the alternating layers is Li and Ni layers about 2 nm, but as the graph compares different dielectric layers thickness and different total number of dielectric layers, the total device thickness varies. It should be noted from FIG. 14 that the best performance is achieved with lipids, and in particular with Al and AU electrode pairs. It should also be appreciated from this graph that when the dielectric layer is a lipid, the piezoelectric charge constant of the PZT5 ceramics is readily exceeded with at least about 100 total dielectric layers when the dielectric thickness of the lipid (or another dielectric materials of similar properties) is about 1,000 nm or less. However, if the dielectric thickness is 10⁴ nm or less, it is preferable to provide at least 1,000 layers. Accordingly, a preferred embodiment of the invention is the use of lipids a the dielectric layers, as they can be uniformly deposited a controlled thicknesses within this range by known techniques, and require relatively fewer layers and separate metallization cycles to achieve surprisingly high performance compared with ceramic piezoelectric materials.

When the dielectric layer is a firmer material, that it has higher elastic modulus than a lipid, such as PMMA, the thickness of the dielectric layer is preferably less than about 300 nm, with a total device thickness of at least about 5 mm.

While the invention has been described in connection with a preferred embodiment, it is not intended to limit the scope of the invention to the particular form set forth, but on the contrary, it is intended to cover such alternatives, modifications, and equivalents as may be within the spirit and scope of the invention as defined by the appended claims.

I claim:

1. A synthetic piezoelectric material comprising:
a) two or more layered repeat units of a first layered structure having the sequential the ordered structure of:
i) a first dielectric material,
ii) a first conductive layer disposed on the dielectric material
iii) a second dielectric material disposed on the first conductive material
iv) a second conductive layer disposed on the second dielectric material wherein when the first and second conductive layers are metals and the work function of the first metal differs from the work function of the second metal,
b) a first terminal connecting all the first conductive layers in said two or more layered repeat units,
c) a second terminal connecting all the second conducting layers in said two or more layered repeat units wherein the first and second conductive layers are electrically isolated by the intervening dielectric materials.

2. A synthetic piezoelectric material according to claim 1 wherein the first and second dielectric material are non-inherently piezoelectric materials.

3. A synthetic piezoelectric material according to claim 1 having a dielectric charge constant that is greater than about 590 pC/N.

4. A synthetic piezoelectric material according to claim 1 comprising at least about 50 layered repeat units wherein the synthetic piezoelectric material has at least 100 of the first and second dielectric layers.

5. A synthetic piezoelectric material according to claim 4 wherein the thickness of a substantial portion of the first and second dielectric layers is 10⁴ nm or less.

6. A synthetic piezoelectric material according to claim 1 wherein the first and second dielectric are lipids having a thickness of less than about 10⁴ nm and the synthetic piezoelectric material has at least about 1,000 lipid layers.

7. A synthetic piezoelectric material according to claim 4 wherein the first and second dielectric are lipids having a thickness of less than about 10³ nm and the synthetic piezoelectric material has at least about 1,000 lipid layers.

8. A synthetic piezoelectric material according to claim 4 wherein the first and second dielectric are lipids having a thickness of less than about 10³ nm and at least 100 lipid layers.

9. A synthetic piezoelectric material according to claim 1 having a piezoelectric charge constant that is proportional to the thickness of the device h, to the contact potential φ and inversely proportional to both the stiffness E and to the square of the thickness of the dielectric layer d.

10. A synthetic piezoelectric material according to claim 1 that exhibits a deformation in response to an applied voltage, wherein the magnitude of the deformation is proportion to the square of the applied voltage.

11. A synthetic piezoelectric material according to claim 1 having at least 100 dielectric layers with a thickness of less than about 10⁴ nm.

12. A synthetic piezoelectric material according to claim 1 wherein at least one of the dielectric materials is an organic material.

13. A synthetic piezoelectric material according to claim 1 wherein the organic material is polymeric.

14. A synthetic piezoelectric material according to claim 1 wherein said dielectric materials are not the same.

15. A synthetic piezoelectric material according to claim 1 wherein said conductive layers consist essentially of the same metal and the alternating layer of the metal are treated by a self assembled monolayer in order to change the working function of the metal.

16. A synthetic piezoelectric material according to claim 16 where the first and second dielectric layers are lipids.

17. A composition of matter exhibiting direct and indirect piezoelectric effects that comprises fifty or more layered units of a first layered structure having the sequential the ordered structure of:
a) a first dielectric material having a thickness less than about 10⁴ nm
b) a first conductive layer disposed on the dielectric material
c) a second dielectric material having a thickness less than about 10⁴ nm disposed on the first conductive material
d) a second conductive layer disposed on the second dielectric material wherein when the first and second conductive layers are metal the work function of the first metal differs from the work function of the second metal,
e) a first terminal connecting all the first conductive layers in said two or more layered repeat units
f) a second terminal connecting all the second conducting layers in said two or more layered units wherein the first and second conductive layers are electrically by the intervening dielectric materials.

18. A composition of matter according to claim 17 having a piezoelectric charge constant that is proportional to the thickness of the device h, to the contact potential φ and inversely proportional to both the stiffness E and to the square of the thickness of the dielectric layer d.

19. A composition of matter according to claim 23 that exhibits a deformation in response to an applied voltage, wherein the magnitude of the deformation is proportion to the square of the applied voltage.

20. A process for generating electric power from the synthetic piezoelectric material of claim, the process comprising the steps of:
a) providing the synthetic piezoelectric material of claim 1;
b) applying stress to the synthetic piezoelectric material,
c) receiving electric current flowing between the first and second terminals.
